(19) United States
(12) Patent Application Publication
(10) Pub. No.: US 2023/0221348 A1
(43) Pub. Date: Jul. 13, 2023

(54) LAMINATED STRUCTURE FOR THERMAL CONDUCTION IN A FLEXIBLE ELECTRICAL SUBSTRATE

(71) Applicant: Tektronix, Inc., Beaverton, OR (US)

(72) Inventor: Julie A. Campbell, Beaverton, OR (US)

(73) Assignee: Tektronix, Inc., Beaverton, OR (US)

(21) Appl. No.: 18/060,463

(22) Filed: Nov. 30, 2022

Related U.S. Application Data
(60) Provisional application No. 63/298,191, filed on Jan. 10, 2022.

(51) Int. Cl. G01R 1/067; H05K 1/02; C09J 7/30; C09J 11/04; B32B 9/00

(52) U.S. Cl. CPC G01R 1/067; H05K 1/0201; C09J 7/30; C09J 11/04; B32B 9/007; H05K 2201/0326; C09J 2203/326; C09J 2301/408; C09J 2400/12; B32B 7/12

(57) ABSTRACT

A structure has a flexible thermally conductive material having an adhesive surface and a non-adhesive surface, and a thermally conductive adhesive adhered to the adhesive surface of the flexible thermally conductive material leaving the non-adhesive surface exposed to an atmosphere in which the structure resides. A structure has a substrate having one or more conductive paths, and a flexible, thermally conductive material attached to at least a portion of the substrate to draw heat away from the conductive paths. An apparatus has a substrate having one or more conductive paths, a probe tip at one end of the substrate configured to electronically connect with a device under test, and a flexible, thermally conductive material attached to at least a portion of the substrate to draw heat away from the probe tip and conductive paths.

### RELATED APPLICATIONS

This disclosure claims benefit of U.S. Provisional Application No. 63/298,191, titled “LAMINATED STRUCTURE FOR THERMAL CONDUCTION IN A FLEXIBLE ELECTRICAL SUBSTRATE,” filed on Jan. 10, 2022, the disclosure of which is incorporated herein by reference in its entirety.

### TECHNICAL FIELD

This disclosure relates to thermal management in test and measurement instruments, more particularly to flexible circuits used in test and measurement instruments.

### BACKGROUND

Many users of test and measurement instruments, such as oscilloscopes, need to test and qualify devices under test (DUTs) at very high temperatures. For example, automotive electronics designers have operating temperature requirements for tests at 125° C., and soon 150° C., due to the extreme environments in which automotive hardware must function. In some cases, automotive components may employ flexible cables and other substrates. One such example includes test probes for test and measurement instruments.

Users need test and measurement probes capable of withstanding high temperatures when inserted into these extreme test environments. In addition, many DUTs involve numerous parts that are complicatedly intertwined. To navigate these complex DUT environments, test and measurement probes must have flexible tips that protect the delicate connection between the DUT and tip end from the strain on the probe body. Probe tips must also be as small and thin as possible to fit in the tight places between interconnected components.

Many probe tips use materials, including cables and substrates, that can only withstand 125° C. Kapton-based and Teflon-based flex circuit tip materials have been used to address this problem, and these flex circuit tip materials have also proven to be very flexible. However, some probes also include a precision amplifier at the tip to help maintain low loading on the DUT signal, acting as a buffer. Keeping this buffer amp near the point of contact lowers the capacitive draw on the signal, but it also more directly exposes the buffer amplifier to the heat of the extreme test environments than if it were further from the point of contact. These buffer amplifiers, often implemented as application-specific integrated circuits (ASICs), cannot operate properly in environments above 105° C., partly because of the concentrated power density and low thermal conductivity of the flex materials. In more extreme test environments, these buffer amplifiers generate very concentrated hot spots that interfere with performance. As such, a probe that enables better thermal spreading at high temperatures while not sacrificing flexibility and small size is needed.

Embodiments of the disclosed structure and methods address shortcomings in the prior art.

### BRIEF DESCRIPTION OF THE DRAWINGS

FIG. 1 shows a test and measurement probe including a flexible, thermally conductive electrical substrate.

FIG. 2 shows an embodiment of a flexible, thermally conductive adhesive.

FIG. 3 shows a layered structure of a flexible, thermally conductive electrical substrate.

### DETAILED DESCRIPTION

Embodiments of the disclosure include a test and measurement probe having a layered structure for conducting heat away from sensitive electrical components and a method of manufacturing the layered structure. The embodiments allow circuit elements to function in environments having temperatures far above 105° C. The operating temperature range may be in the range of over 135° C., and even over 150° C.

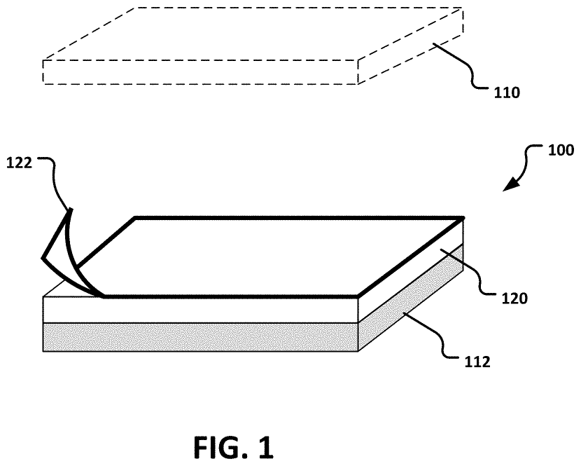

FIG. 1 shows an embodiment of a thermally conductive structure 100. In the embodiment of FIG. 1, the thermally conductive structure 100 comprises a thin, flexible, thermally conductive material 112 and a thermally conductive, flexible adhesive 120. Other thermally conductive materials may not require adhesives or may themselves be an adhesive with a cover layer, like tape, that prevents one side of the adhesive from adhering to anything.

In the embodiment of FIG. 1, the thermally conductive, flexible adhesive has a removable backing on one side of the adhesive, not shown, that allows the thermally conductive material 112 to attach to the adhesive 120. The other side of the adhesive 120 may also have a removable backing 122 that would then allow the adhesive to attach the thermally conductive material 112 to a substrate 110. The thermally conductive material has two surfaces. The first surface is “sticky” or adhesive and the other is non-adhesive. The adhesive 120 attaches the adhesive surface of the thermally conductive material, and leaves the non-adhesives surface exposed to the atmosphere in which structure resides, typically air, but other environments as well. This allows for better dissipation of heat.

In one embodiment, the structure comprises the flexible, thermally conductive material and the thermally conductive adhesive. Another embodiment of the structure comprises the flexible thermally conductive material and the substrate, with or without the adhesive.

In some embodiments, the flexible, thermally conductive material 112 may be pyrolytic graphite, but other materials of similar flexibility and thermal conductivity may be used. In some embodiments, the adhesive 120 may comprise a thermally conductive tape with sticky surfaces on two sides, although other flexible and thermally conductive adhesives may also be appropriate. The thermally conductive tape could attach to the flexible, thermally conductive material by other means, such as heat curing, etc., and only have the removable backing on one side. In some embodiments, the thermally conductive adhesive may include highly thermally conductive ceramic or other beads.

Using an adhesive having thermally conductive properties allows the thermally conductive material 112 to be adhered to other materials without inhibiting the conductivity of the thermally conductive material itself.

The substrate may comprise a flex circuit substrate, or may be a rigid substrate like a more conventional printed circuit board. The surface of the substrate may be flat, referred to here as planar, or it may have structures of differing heights protruding from the substrate, or is otherwise not flat, referred to here as non-planar.

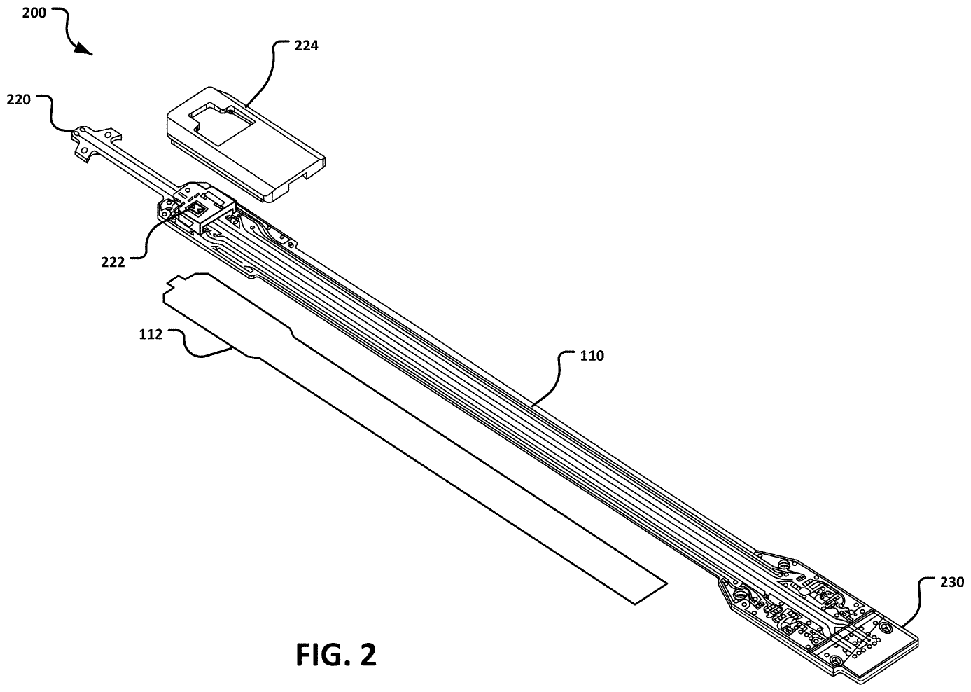

FIG. 2 shows an embodiment of a test and measurement probe 200. This embodiment demonstrates a use of the thermally conductive structure of FIG. 1 to control heat in hot and tightly spaced environments. Other electrical and mechanical structures may employ the flexible, thermally conductive material.

The body of the test and measurement probe 200 is made of a flexible substrate 110 with a layered structure. This comprises merely one embodiment, as the substrate 110 could comprise any type of substrate that requires heat dissipation. The test and measurement probe 200 also includes a probe tip 220 for electrically connecting to a device under test (DUT) to a test and measurement instrument, not shown. This connection may occur through the test and measurement instrument interface 230.

In some instances, an application-specific integrated circuit (ASIC), or other electronic component, 222 may reside on the probe tip. The reference to this component as an ASIC does not limit the component to an ASIC. The ASIC 222 may comprise a buffer/amplifier and lower the capacitive draw on the signal. This buffer will generally not function properly in environments over 105° C. The ASIC 222 itself may also comprise a heat generator in the confines of the environments in which the probe operates.

The ASIC 222 may also include a protective cover 124. A thermally conductive layer 112, such as that in structure 100 of FIG. 1, is attached to a portion of the flexible substrate 110, allowing heat to be conducted along the length of the test and measurement probe 200 and away from the probe tip 220 and ASIC 222. In some embodiments, the thermally conductive layer 112 may attach to a bottom surface of the flexible substrate 110 with an adhesive.

As mentioned, the flexible substrate 110 may comprise a layered structure having one or more conductive layers and one or more electrically insulative layers. The conductive layers may comprise a layer of printed circuit traces, and the insulative layer may comprise Kapton or Teflon.

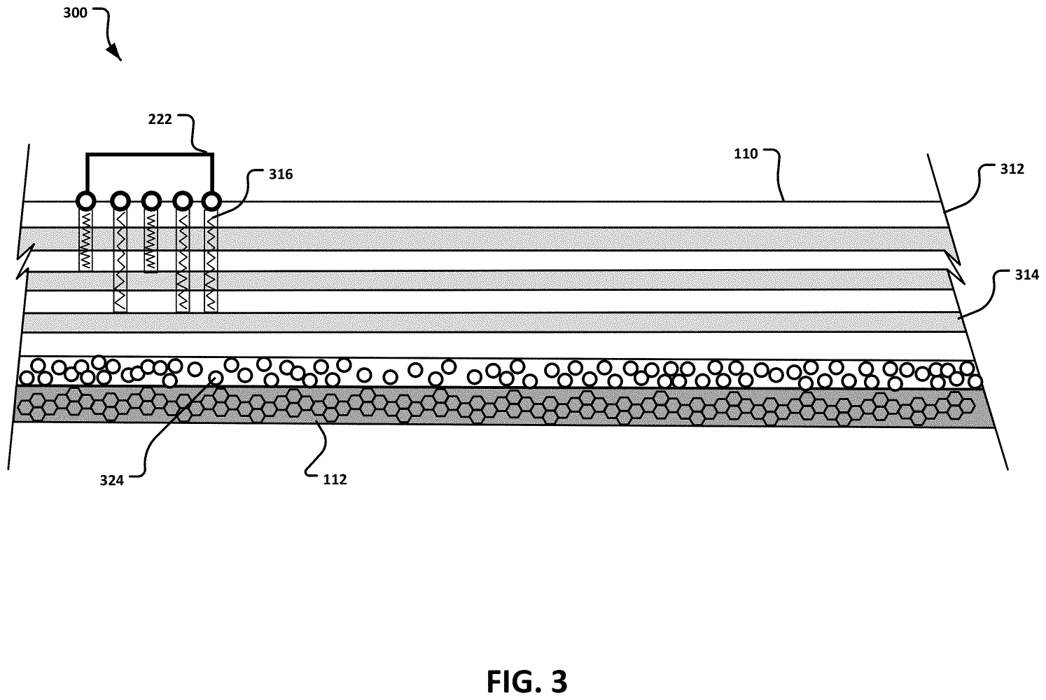

FIG. 3 shows a cross section of a layered structure 300 having the flexible thermally conductive material 112 adhered to the flexible substrate 110. As shown, the flexible substrate 110 itself has a layered structure that includes alternating layers of insulative material 312 and conductive material 314. The layers of conductive material 314 provide conductive paths such as 316 for electrical connection for the ASIC 222, the probe tip 220, and the instrument interface 230, shown in FIG. 2. The layers of insulative material 312 provide electrical insulation between the layers of conductive traces and may aid in protection of the electrical components in high-temperature environments.

FIG. 3 shows the flexible substrate 110 adhered to the thermally conductive material 112. In some embodiments, the adhesive 120 of FIG. 1 may be used, and the adhesive 120 may include a number of ceramic beads 324 to contribute to the thermal conductivity of the adhesive 120. Applying this layered structure 300 to the test and measurement probe 100, the thermally conductive material 112 acts as a heat sink and draws heat along the length of the test and measurement probe 100 and away from the probe tip 220 and ASIC 222, without sacrificing needed flexibility. Accordingly, when the test and measurement probe 100 is inserted into and navigated through a high-temperature environment to probe a DUT, the probe tip 220 and ASIC 222 may continue to operate properly in the high temperature environment. Heat spreads along the body of the test and measurement probe 100 rather than concentrated directly at the probe tip 220 and ASIC 222.

Although embodiments of the disclosure refer to application of the layered structure 300 to a test and measurement probe 100, it should be noted that the layered structure 300 shown in FIG. 3 may be stamped into any desired shape in manufacturing for a variety of applications. As stated above, one surface of the thermally conductive material remains exposed to the atmosphere.

A method of manufacturing the thermally and electrically conductive component or structure may take many forms. In one embodiment, the process creates a substrate. This may involve alternating one or more layers of a material having electrically conductive material, typically laid out as circuit traces with one or more layers of electrically insulative material in an alternating fashion to create a flexible substrate. The process then attaches a sheet of flexible, thermally conductive material to at least a portion of the substrate to produce a laminated sheet. The laminated sheet could then undergo stamping to form a component of the desired shape.

In one embodiment attaching the sheet of flexible, thermally conductive material to at least a portion of the substrate involves using a flexible, thermally conductive adhesive.

In one embodiment the flexible, thermally conductive adhesive includes thermally conductive ceramic beads.

In one embodiment, the flexible, thermally conductive material includes at least one layer of pyrolytic graphite.

In this manner, the embodiments provide electrically conductive substrates with thermal control to allow their use in hot, and tightly spaced, or enclosed environments. Using a flexible thermally conductive material directs the heat away from the conductive traces and any electronic devices on the substrate to allow the circuit to operate properly.

Additionally, this written description makes reference to particular features. It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

### EXAMPLES

Illustrative examples of the disclosed technologies are provided below. An embodiment of the technologies may include one or more, and any combination of, the examples described below.

Example 1 is a structure comprising a flexible thermally conductive material having an adhesive surface and a non-adhesive surface; and a thermally conductive adhesive adhered to the adhesive surface of flexible thermally conductive material, leaving the non-adhesive surface exposed to an atmosphere in which the structure resides.

Example 2 is the structure of Example 1, wherein the thermally conductive adhesive is adhered to a substrate having conductive paths.

Example 3 is the structure of Example 2, wherein the substrate is at least one of planar, non-planar, rigid or flexible.

Example 4 is the structure of Example 2, wherein the substrate includes a probe tip at one end of the substrate configured, the probe tip to electrically connect with a device under test.

Example 5 is the structure of Example 4, wherein the structure includes an application-specific integrated circuit electrically connected to the probe tip.

Example 6 is the structure of any of Examples 1 through 5, wherein the thermally conductive adhesive includes thermally conductive ceramic beads.

Example 7 is the apparatus of any of Examples 1 through 6, wherein the thermally conductive adhesive includes at least one layer of pyrolytic graphite.

Example 8 is a structure comprising: a substrate having one or more conductive paths; and a flexible, thermally conductive material attached to at least a portion of the substrate to draw heat away from the conductive paths.

Example 9 is the structure of Example 8, wherein the substrate is at least one of planar, non-planar, rigid or flexible.

Example 10 is the structure of either of Examples 8 or 9, wherein the structure includes a thermally conductive, flexible adhesive between the substrate and the flexible, thermally conductive material to join the substrate and the flexible, thermally conductive material.

Example 11 is the structure of any of Examples 8 through 10, wherein the structure includes a probe tip at one end of the substrate configured to electronically connect with a device under test.

Example 12 is the structure of any of Examples 8 through 11, wherein the structure includes an application-specific integrated circuit electrically connected to the probe tip.

Example 13 is the structure of any of Examples 8 through 11, wherein the structure interfaces with a test and measurement instrument via cables electrically connected to the one or more conductive paths at one end of the flexible substrate.

Example 14 is the structure of Example 9, wherein the thermally conductive, flexible adhesive includes thermally conductive ceramic beads.

Example 15 is the structure of any of Examples 8 through 14, wherein the flexible, thermally conductive material includes at least one layer of pyrolytic graphite.

Example 16 is an apparatus, comprising: a substrate having one or more conductive paths; a probe tip at one end of the substrate configured to electronically connect with a device under test; and a flexible, thermally conductive material attached to at least a portion of the substrate to draw heat away from the probe tip and conductive paths.

Example 17 is the apparatus of Example 16, wherein the apparatus includes an application-specific integrated circuit electrically connected to the probe tip.

Example 18 is the apparatus of either of Examples 16 or 17, wherein the apparatus interfaces with a test and measurement instrument via cables electronically connected to the one or more conductive paths at one end of the flexible substrate.

Example 19 is the apparatus of any of Examples 16 through 18, wherein the apparatus includes an adhesive between the substrate and the flexible, thermally conductive material to join the substrate to the flexible, thermally conductive material.

Example 20 is the apparatus of any of Examples 16 through 18, wherein the apparatus can operate at temperatures up to 150° C.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Although specific embodiments have been illustrated and described for purposes of illustration, it will be understood that various modifications may be made without departing from the spirit and scope of the disclosure. Accordingly, the invention should not be limited except as by the appended claims.

We claim:

1. A structure, comprising
a flexible thermally conductive material having an adhesive surface and a non-adhesive surface; and
a thermally conductive adhesive adhered to the adhesive surface of the flexible thermally conductive material leaving the non-adhesive surface exposed to an atmosphere in which the structure resides.

2. The structure as claimed in claim 1, wherein the thermally conductive adhesive is adhered to a substrate having conductive paths.

3. The structure as claimed in claim 2, wherein the substrate is at least one of planar, non-planar, rigid or flexible.

4. The structure as claimed in claim 2, wherein the substrate includes a probe tip at one end of the substrate configured, the probe tip to electrically connect with a device under test.

5. The structure as claimed in claim 4, wherein the structure includes an application-specific integrated circuit electrically connected to the probe tip.

6. The structure as claimed in claim 1, wherein the thermally conductive adhesive includes thermally conductive ceramic beads.

7. The apparatus as claimed in claim 1, wherein the thermally conductive adhesive includes at least one layer of pyrolytic graphite.

8. A structure comprising:
a substrate having one or more conductive paths; and
a flexible, thermally conductive material attached to at least a portion of the substrate to draw heat away from the conductive paths.

9. The structure as claimed in claim 8, wherein the substrate is at least one of planar, non-planar, rigid or flexible.

10. The structure as claimed in claim 8, wherein the structure includes a thermally conductive, flexible adhesive between the substrate and the flexible, thermally conductive material to join the substrate and the flexible, thermally conductive material.

11. The structure as claimed in claim 8, wherein the structure includes a probe tip at one end of the substrate configured to electronically connect with a device under test.

12. The structure as claimed in claim 8, wherein the structure includes an application-specific integrated circuit electrically connected to the probe tip.

13. The structure as claimed in claim 8, wherein the structure interfaces with a test and measurement instrument via cables electrically connected to the one or more conductive paths at one end of the flexible substrate.

14. The structure as claimed in claim 9, wherein the thermally conductive, flexible adhesive includes thermally conductive ceramic beads.

15. The structure as claimed in claim 8, wherein the flexible, thermally conductive material includes at least one layer of pyrolytic graphite.

16. An apparatus, comprising:
a substrate having one or more conductive paths;
a probe tip at one end of the substrate configured to electronically connect with a device under test; and
a flexible, thermally conductive material attached to at least a portion of the substrate to draw heat away from the probe tip and conductive paths.

17. The apparatus as claimed in claim 16, wherein the apparatus includes an application-specific integrated circuit electrically connected to the probe tip.

18. The apparatus as claimed in claim 16, wherein the apparatus interfaces with a test and measurement instrument via cables electronically connected to the one or more conductive paths at one end of the flexible substrate.

19. The apparatus as claimed in claim 16, wherein the apparatus includes an adhesive between the substrate and the flexible, thermally conductive material to join the substrate to the flexible, thermally conductive material.

20. The apparatus as claimed in claim 16, wherein the apparatus can operate at temperatures up to 150° C.
